(19) United States
(12) Patent Application Publication
(10) Pub. No.: US 2017/0207079 A1
(43) Pub. Date: Jul. 20, 2017

(54) SUBSTRATE CLEANING METHOD

(71) Applicant: UNITED MICROELECTRONICS CORP., Hsin-Chu City (TW)

(72) Inventors: Chia-Ming Lee, Tainan City (TW); Kuo-Wei Chih, Chiayi City (TW); Chen-Hsu Hung, Chiayi City (TW); Chun-Li Lin, Kaohsiung City (TW); Chia-Yen Hsu, Kaohsiung City (TW); Tsung-Hsun Tsai, Chiayi County (TW); Po-Lun Cheng, Kaohsiung City (TW)

(21) Appl. No.: 14/996,238

(22) Filed: Jan. 15, 2016

(51) Int. Cl. H01L 21/02; B08B 3/08; B08B 3/02

(52) U.S. Cl. CPC H01L 21/02057; B08B 3/02; B08B 3/08

(57) ABSTRACT

A substrate cleaning method is provided. A substrate is provided, followed by performing a first pre-cleaning process with a first rotation speed and a first duration time. After the first pre-cleaning process, a second pre-cleaning process is performed with a second rotation speed and a second duration time, wherein the second rotation speed is greater than the first rotation speed. After the second pre-cleaning process, a cleaning process is performed by using a chemical agent with a cleaning rotation speed.

### BACKGROUND OF THE INVENTION

1. Field of the Invention

The present invention is related to a substrate cleaning method, and more particularly to a substrate cleaning method with multi pre-cleaning processes.

2. Description of the Prior Art

Micro-processor systems comprised of integrated circuits (IC) are ubiquitous devices in modern society, being utilized in such diverse fields as automatic control electronics, mobile communication devices and personal computers. With the development of technology and the increasingly imaginative applications of electrical products, IC devices are becoming smaller, more delicate and more diversified.

When producing electronic devices, dry etching techniques are commonly used to pattern an insulating film or conductive film, for example. When doing so, a known problem is that residue (such as side wall protection film and remaining polymer) that is caused by an etching gas, a photoresist or a processed film is often left around the etched pattern (such as the via holes and wires), formed by the dry etching. If such residue is left in the via holes, for example, problems can result, such as poor connections between the upper and lower wiring layers and increased resistance of the via holes. Also, if residue is present on the side walls of wiring, for example, this can cause short circuits between adjacent wires. In this way, the presence of such residue can drastically reduce the reliability of an electronic device.

In order to remove such residue, it is now common practice to use a cleaning solution that includes various organic or inorganic compounds. Also, in the cleaning process that uses this kind of cleaning solution, or in the rinsing process with water that follows the cleaning process.

### SUMMARY OF THE INVENTION

The present invention therefore provides a substrate cleaning method, so as to thoroughly clean the substrate.

According to one embodiment, a substrate cleaning method is provided. A substrate is provided, followed by performing a first pre-cleaning process with a first rotation speed and a first duration time. After the first pre-cleaning process, a second pre-cleaning process is performed with a second rotation speed and a second duration time, wherein the second rotation speed is greater than the first rotation speed. After the second pre-cleaning process, a cleaning process is performed by using a chemical agent with a cleaning rotation speed.

By utilizing both the first pre-cleaning process and the second pre-cleaning process, both the static electricity and particle (PA) phenomenon can be eliminated.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a flowchart of the substrate cleaning method according to the first embodiment of the present invention.

FIG. 2 shows a flowchart of the substrate cleaning method according to the second embodiment of the present invention.

FIG. 3 shows a flowchart of the substrate cleaning method according to the third embodiment of the present invention.

FIG. 4 shows a schematic diagram of the substrate cleaning method according to one embodiment of the present invention.

FIG. 5 shows a schematic diagram of the rotation speed and the as a function of time according to one embodiment of the present invention.

### DETAILED DESCRIPTION

To provide a better understanding of the present invention, preferred embodiments will be described in detail. The preferred embodiments of the present invention are illustrated in the accompanying drawings with numbered elements.

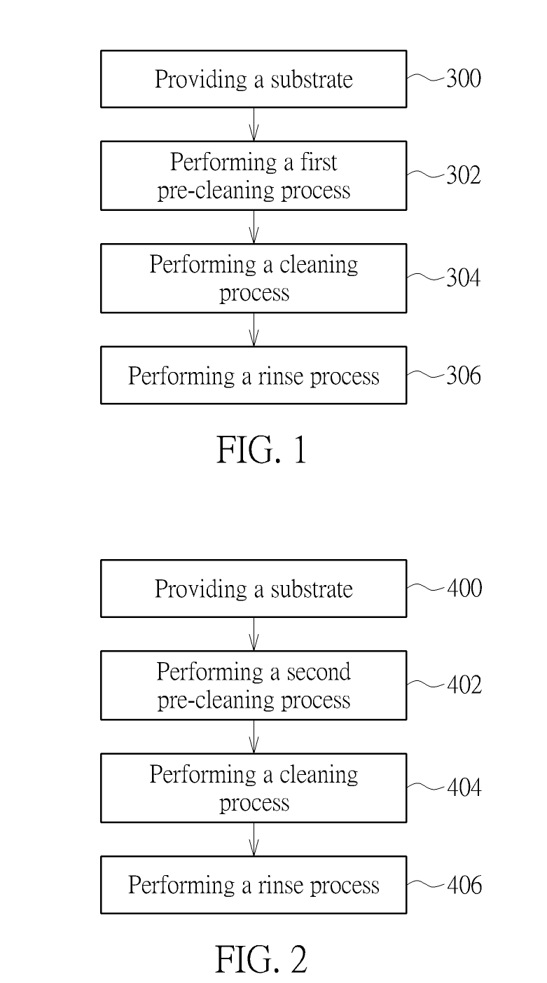

Please refer to FIG. 1, showing a flowchart of the substrate cleaning method according to the first embodiment of the present invention. Please also refer to FIG. 4, which shows a schematic diagram of the substrate cleaning method according to one embodiment of the present invention. AS shown in FIG. 1, a substrate 600 is provided (step 300). The substrate 600 refers to any device or component that has been subjected to a semiconductor process, such as an etching process or a lithography process, and therefore needs a cleaning process to remove unwanted residues or redundant solvent. Next, a first pre-cleaning process is performed (step 302). In one embodiment, the first pre-cleaning process utilizes water 602 to mildly wash the substrate. Preferably, the water is CO₂-dissolved deionized water. The first pre-cleaning process includes a first rotation speed and a first duration time. In one embodiment, the first rotation speed ranges from 10 rpm to 100 rpm and the first duration time is about 30 seconds. Subsequently, a cleaning process is performed (step 304). The cleaning process utilizes a chemical agent to thoroughly clean the wafer, wherein the type of the chemical agent, the cleaning duration time and the cleaning speed are adjusted according to the semiconductor process before the first pre-cleaning and the cleaning process. In one embodiment, the chemical agent includes APM (NH₄OH:H₂O₂:H₂O) , SPM (H₂SO₂ :H₂O) , HPM (HCl:H₂O₂ :H₂O) , FPM (HF:H2O₂ :H₂O), DHF (HF:H₂O), BHF (HF:NH₄F:H₂O), and is not limited thereto. Next, a rinse process is performed (step 306). The rinse process utilizes a chemical agent to clean the wafer. Depending on the semiconductor process before the cleaning process, the type of the chemical agent, the cleaning duration time and the cleaning speed can be altered. In one embodiment, the agent of the rinse process can be deionized water. In another embodiment, the cleaning process and the rinse process are performed repeatedly. By using the first pre-cleaning process with an appropriate rotation speed, for example, 10 rpm to 100 rpm, there would be less static electricity remained on the substrate.

Please refer to FIG. 2, showing a flowchart of the substrate cleaning method according to the second embodiment of the present invention. As shown in FIG. 2, the substrate cleaning process includes the following steps. First, a substrate is provided (step 400). The substrate refers to any device or component that has been subjected to a semiconductor process, such as an etching process, a lithography process, and the like, and therefore needs a cleaning process to remove unwanted residues for example. Next, a second pre-cleaning process is performed (step 402). In one embodiment, the second pre-cleaning process utilizes water to mildly wash the substrate. Preferably, the water is CO₂-dissolved deionized water. The second pre-cleaning process includes a second rotation speed and a second duration time. In one embodiment, the second rotation speed is between 100 rpm and 500 rpm and the second duration time is about 30 seconds. Subsequently, a cleaning process is performed (step 404). The cleaning process utilizes a chemical agent to clean the wafer. The type of the chemical agent, the cleaning duration time and the cleaning speed are adjusted depending on the semiconductor process before the cleaning process. In one embodiment, the chemical agent includes APM (NH₄OH:H₂O₂:H₂O), SPM (H₂SO₂:H₂O), HPM (HCl:H₂O₂:H₂O), FPM (HF:H2O₂:H₂O), DHF (HF:H₂O), BHF (HF:NH₄F:H₂O), and is not limited thereto. Next, a rinse process is performed (step 406). The rinse process utilizes a chemical agent to clean the wafer. Depending on the semiconductor process before the cleaning process, the type of the chemical agent, the cleaning duration time and the cleaning speed can be altered. In one embodiment, the agent of the rinse process is deionized water. In another embodiment, the cleaning process and the rinse process are performed repeatedly. By using the second pre-cleaning process with an appropriate rotation speed, for example, 100 rpm to 500 rpm, the possibility of particle (PA) phenomenon can be reduced. As shown in FIG. 4, the PA phenomenon is caused by water 602 splashing our from the substrate 600, hitting the chamber wall 604 and then back to the substrate 600 (like the arrow A) when rotating the substrate 600. The water 600 remained on the substrate 500 becomes water particle, which will deteriorate the following fabrication steps.

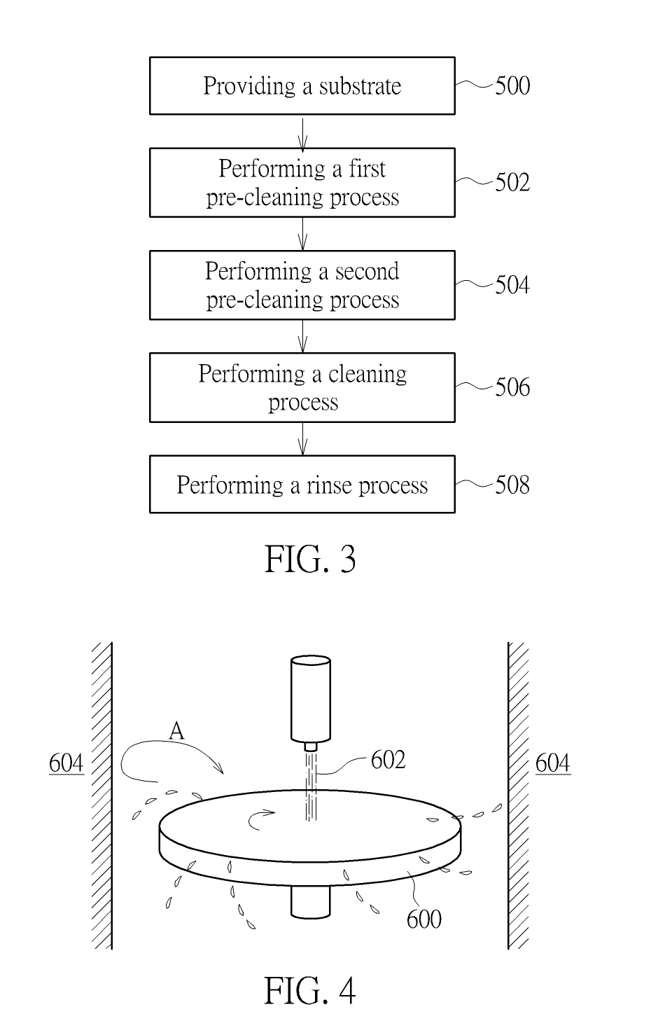

Please refer to FIG. 3, showing a flowchart of the substrate cleaning method according to the third embodiment of the present invention. As shown in FIG. 3, the substrate cleaning process includes the following steps. First, a substrate is provided (step 500). The substrate refers to any device or component that has been subjected to a semiconductor process, such as an etching process, a lithography process, and the like, and therefore needs a cleaning process to remove unwanted residues for example. Next, a first pre-cleaning process is performed (step 502). In one embodiment, the first pre-cleaning process utilizes water to mildly wash the substrate. Preferably, the water is CO₂-dissolved deionized water. The first pre-cleaning process includes a first rotation speed and a first duration time. In one embodiment, the first rotation speed ranges from 10 rpm to 100 rpm and the first duration time is about 18 to 25 seconds.

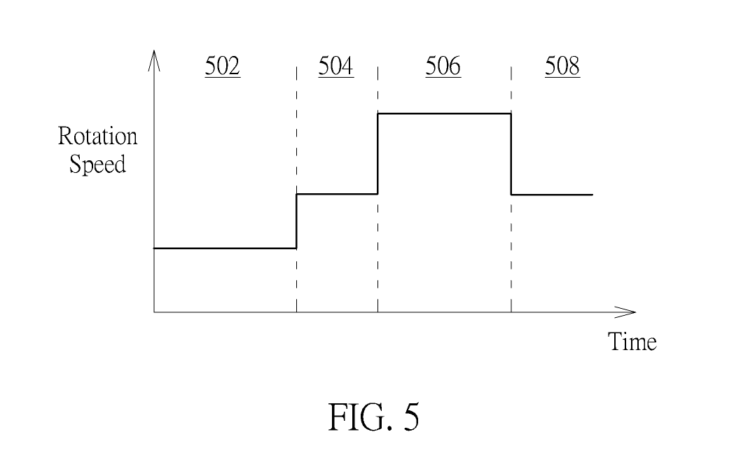

Next, a second pre-cleaning process is performed (step 504). In one embodiment, the second pre-cleaning process utilizes water to mildly wash the substrate. Preferably, the water is CO₂-dissolved deionized water. The second pre-cleaning process includes a second rotation speed and a second duration time. Please refer to FIG. 5, which shows a schematic diagram of the rotation speed and the as a function of time according to one embodiment of the present invention. As shown, in one preferred embodiment, the second rotation speed is greater than the first rotation speed. For example, the second rotation speed is between 100 rpm and 500 rpm. It is another feature that the second duration time is less than the first duration time. In one embodiment, the second duration time is about 5 seconds to 12 seconds. Subsequently, a cleaning process is performed (step 506). The cleaning process utilizes a chemical agent to clean the wafer. The type of the chemical agent, the cleaning duration time and the cleaning speed are adjusted depending on the semiconductor process before the cleaning process. In one embodiment, the chemical agent includes APM (NH₄OH:H₂O₂ :H₂O) , SPM (H₂SO₂ :H₂O) , HPM (HCl:H₂O₂ :H₂O) , FPM (HF:H2O₂:H₂O) , DHF (HF:H₂O) , BHF (HF:NH₄F:H₂O) , and is not limited thereto. In one embodiment, the cleaning rotation speed is greater than the second rotation speed. For instance, the cleaning rotation speed is between 300 and 1100 rpm. However, depending on different requirements, the cleaning rotation speed can be less than the second rotation speed. Next, a rinse process is performed (step 508). The rinse process utilizes a chemical agent to clean the wafer. Depending on the semiconductor process before the cleaning process, the type of the chemical agent, the cleaning duration time and the cleaning speed can be altered. In one embodiment, the agent of the rinse process is deionized water. In another embodiment, the cleaning process and the rinse process are performed repeatedly. It is one salient feature in the present embodiment to include both the first pre-cleaning process and the second pre-cleaning process. Though the first embodiment with the first pre-cleaning process can avoid static electricity, there are still some water drop remained on the substrate (PA phenomenon). On the other hand, the second embodiment with the second pre-cleaning process can avoid PA phenomenon, it is still suffered from static electricity since the rotation speed is relative high. Accordingly, the third embodiment incorporates both the first pre-cleaning process and the second pre-cleaning process, not only can avoid PA phenomenon but also reduce static electricity.

In light of above, the present invention provides a substrate cleaning method. By utilizing both the first pre-cleaning process and the second pre-cleaning process, both the static electricity and PA phenomenon can be eliminated.

Those skilled in the art will readily observe that numerous modifications and alterations of the device and method may be made while retaining the teachings of the invention. Accordingly, the above disclosure should be construed as limited only by the metes and bounds of the appended claims.

1. A substrate cleaning method, comprising:
providing a substrate;
performing a first pre-cleaning process with a first rotation speed and a first duration time, the first pre-cleaning process comprising supplying CO₂-dissolved DI water;
after the first pre-cleaning process, performing a second pre-cleaning process with a second rotation speed and a second duration time, the second pre-cleaning process comprising supplying CO₂-dissolved DI water, wherein the second rotation speed is greater than the first rotation speed and the first duration time is greater than the second duration time; and
after the second pre-cleaning process, performing a cleaning process by using a chemical agent with a cleaning rotation speed.

2. The substrate cleaning method according to claim 1, wherein the first rotation speed is between 10 rpm and 100 rpm.

3. The substrate cleaning method according to claim 1, wherein the second rotation speed is between 100 rpm and 500 rpm.

4. (canceled)

5. The substrate cleaning method according to claim 1, wherein the first duration time is 18 to 25 seconds.

6. The substrate cleaning method according to claim 1, wherein the second duration time is 5 to 12 seconds.

7. The substrate cleaning method according to claim 1, wherein the cleaning rotation speed is greater than the second rotation speed.

8. The substrate cleaning method according to claim 1, wherein the cleaning rotation speed is between 300 and 1100 rpm.

9. (canceled)

10. (canceled)

11. The substrate cleaning method according to claim 1, wherein after the cleaning process, further comprising a rinse process.

12. The substrate cleaning method according to claim 11, wherein the cleaning process and the rinse process are performed repeatedly.
